(19) United States
(12) Patent Application Publication
(10) Pub. No.: US 2004/0262772 A1
(43) Pub. Date: Dec. 30, 2004

(54) Methods for bonding wafers using a metal interlayer

(76) Inventors: Shriram Ramanathan, Hillsboro, OR (US); Ramanan Chebiam, Hillsboro, OR (US); Mauro J. Kobrinsky, Hillsboro, OR (US); Valery Dubin, Portland, OR (US); Scott List, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/611,395

(22) Filed: Jun. 30, 2003

(51) Int. Cl. H01L 21/44; H01L 23/48; H01L 29/40; H01L 21/30

(52) U.S. Cl. 257/777; 438/455; 438/598; 438/109; 257/782

(57) ABSTRACT

Embodiments of a method of bonding wafers together using a metal interlayer deposited on conductors of each wafer. Also disclosed is a wafer stack formed according to the method of wafer bonding using a metal interlayer.

### FIELD OF THE INVENTION

The invention relates generally to wafer bonding and, more particularly, to methods of bonding patterned wafers together using a metal interlayer.

### BACKGROUND OF THE INVENTION

Current technology for fabricating integrated circuits produces a two-dimensional structure. For a given process technology, an increase in performance and functionality of an optimized design is accompanied by a corresponding increase in die size. However, die size is not, in practice, unbounded. As both processor frequencies and die size increase, a growing number of clock cycles will be necessary for communications across a larger sized die, and this interconnect delay may be unsuitable for high performance applications. Moreover, although scaling down of transistor dimensions can make the transistors faster, connecting them requires an increasing number of wires. A possible solution to meeting the wire demands is to decrease the wire dimensions, but this approach can degrade their performance by increasing delay. The current trends in the industry are decreasing transistor delays and increasing interconnect delays, which inevitably will result in interconnect-limited processor performance. Also, the demand for smaller personal computers (e.g., laptop computers) and the increasing popularity of hand-held computing devices—e.g., mobile phones, tablet computers, personal digital assistances (or PDAs), and the like—are pushing manufacturers to develop integrated circuit (IC) devices having a smaller form factor (e.g., decreased die area, volume, and weight). In addition, incompatible process flows inhibit the integration of different technologies—e.g., optical and electrical, RF (radio frequency) and logic, memory and logic, etc.—onto a single die, an architecture often referred to as “system-on-chip” (or SOC). Furthermore, conventional photolithography techniques may not scale to larger die sizes while providing sufficient resolution and uniformity. These factors, as well as others such as cost, are motivating IC manufacturers to search for three-dimensional solutions.

One three-dimensional solution that has emerged is “wafer stacking.” Generally, wafer stacking is the bonding together of two or more semiconductor wafers upon which integrated circuitry has been formed. The wafer stack is subsequently diced into separate “stacked die,” each stacked die having multiple layers of integrated circuitry. Wafer stacking technology offers a number of potential benefits. For example, IC devices formed by wafer stacking techniques may provide enhanced performance and functionality (e.g., SOC solutions) while lowering costs and improving form factors. System-on-chip architectures formed by wafer stacking can enable high bandwidth connectivity between stacked die with dissimilar technologies—e.g., logic circuitry and dynamic random access memory (DRAM)—that otherwise have incompatible process flows. Also, by using three-dimensional technologies, smaller die sizes can be achieved resulting in a significant decrease in interconnect delays, which increases performance while decreasing power and, potentially, cost. Furthermore, although incompatible processes may be used to form integrated circuitry on the various wafers of a wafer stack, each layer of the stack can be fabricated using existing process flows and technology. There are many potential applications for wafer stacking technology, including high performance processing devices, video and graphics processors, high density and high bandwidth memory chips, and SOC solutions, as noted above.

Wafer stacking does, however, present a number of technological challenges. To achieve the potential benefits of wafer stacking described above, while also maintaining reliability, a number of issues need to be addressed, including reducing the inter-wafer pitch, providing efficient heat extraction and power delivery, providing a satisfactory compound yield, and providing a wafer bonding process that is reliable and cost effective. Current wafer bonding processes include adhesive bonding and metallic bonding.

In adhesive bonding, a wafer stack is formed by bonding adjacent wafers together using a layer of adhesive. Adhesive wafer bonding does, however, suffer from a need for very high aspect ratio vias for every die-to-die interconnect, which may have reliability and resistance problems, as well as a need for a void-free adhesive layer between the bonded wafers.

In metallic wafer bonding, two wafers are joined by directly bonding the metal conductors formed on one of the wafers with corresponding metal conductors formed on the other wafer. Current metallic wafer bonding techniques also suffer from a number of drawbacks. The metal conductors are typically constructed of Copper (Cu), and bonding Copper to Copper generally requires moderate to high temperatures for relatively long periods of time (e.g., at temperatures exceeding 400° C. for 30 minutes or longer). The long bonding time leads to greater processing time and, hence, lower throughput and increased cost. Also, higher temperatures can result in significant stresses due to thermal mismatches, which is a reliability concern. In addition, problems such as the poor corrosion resistance of Copper (i.e., Copper readily forms a native oxide in the presence of Oxygen), electromigration of Copper into surrounding structures, and metal height variability at the bond interface can all (either individually or in combination) lead to poor reliability of the metal-to-metal bond.

### BRIEF DESCRIPTION OF THE DRAWINGS

FIG. 1 is a block diagram illustrating an embodiment of a method for wafer bonding using a metal interlayer.

FIGS. 2A-2G are schematic diagrams illustrating an embodiment of the method of wafer bonding shown in FIG. 1.

FIGS. 3A-3B are schematic diagrams illustrating an embodiment of a process for depositing a metal interlayer on conductors of a wafer.

FIG. 4 is a schematic diagram illustrating another embodiment of a process for depositing a metal interlayer on conductors of a wafer.

FIGS. 5A-5B are schematic diagrams illustrating a further embodiment of a process for depositing a metal interlayer on conductors of a wafer.

FIGS. 6A-6B are schematic diagrams illustrating yet another embodiment of a process for depositing a metal interlayer on conductors of a wafer.

FIG. 7 is a schematic diagram illustrating another embodiment of the method of wafer bonding shown in FIG. 1.

FIG. 8 illustrates a binary phase diagram for Silver (Ag) and Copper.

### DETAILED DESCRIPTION OF THE INVENTION

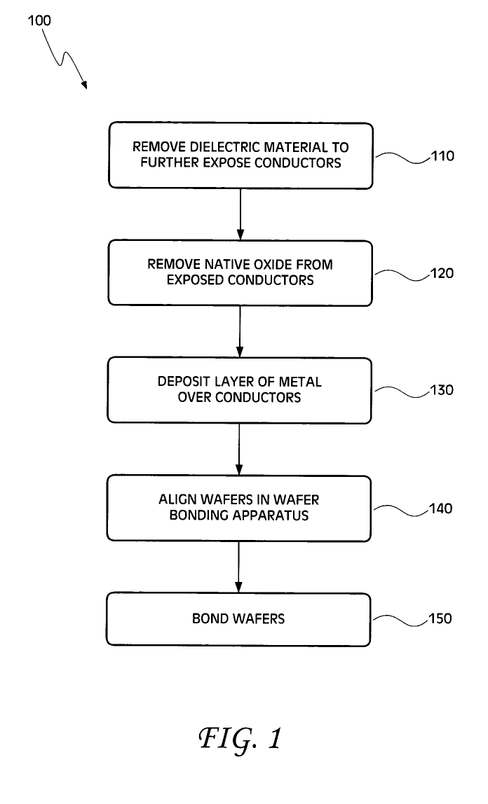

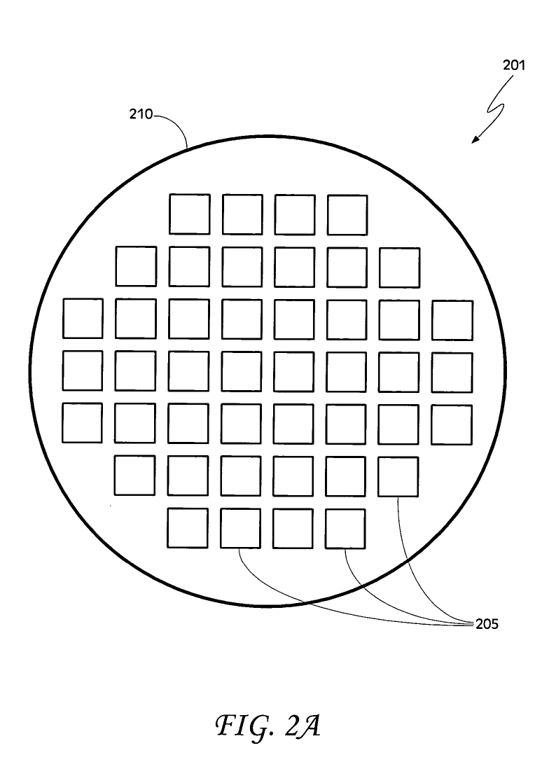

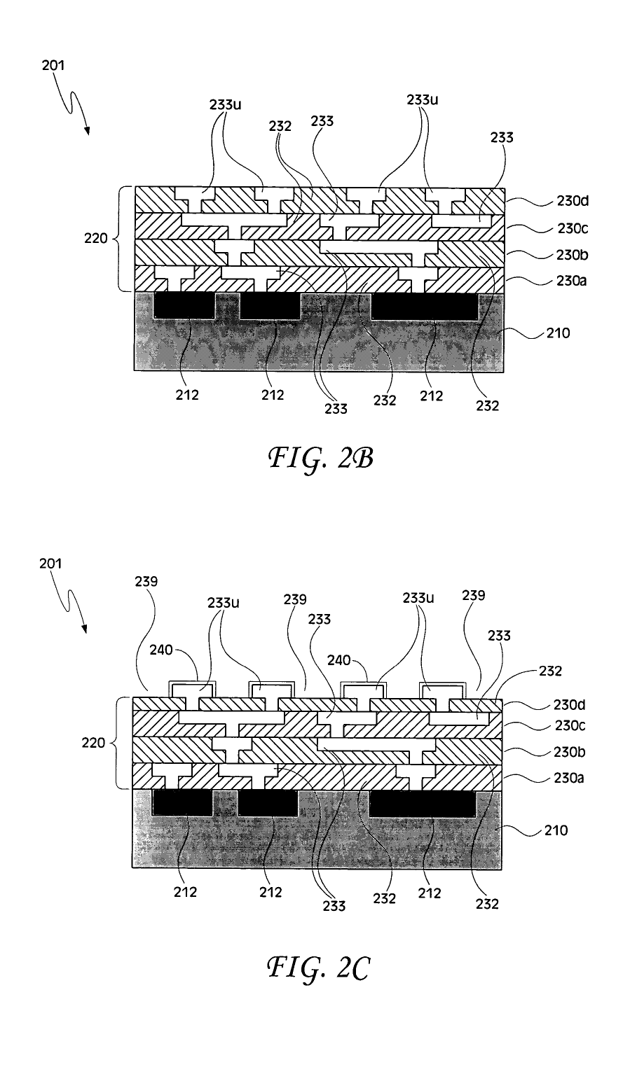

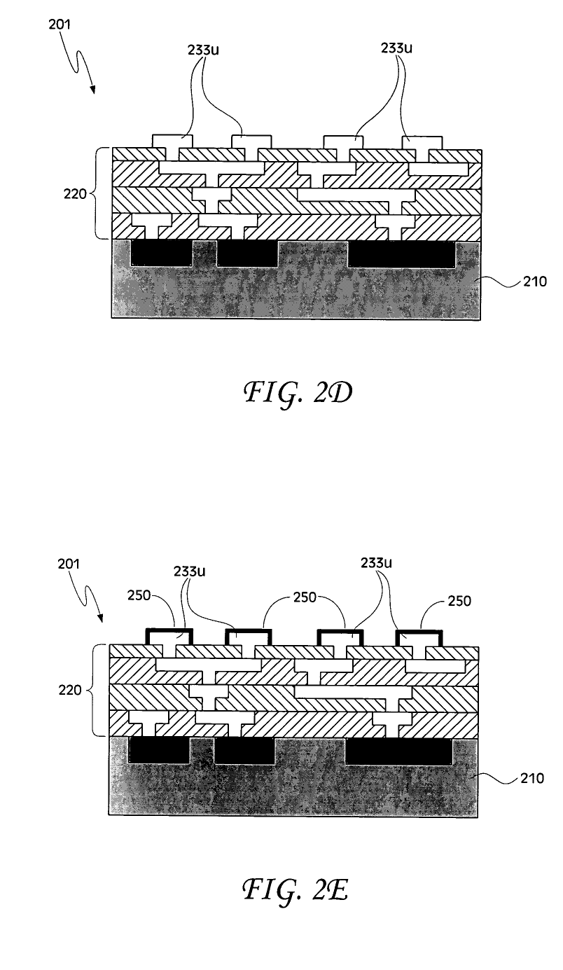

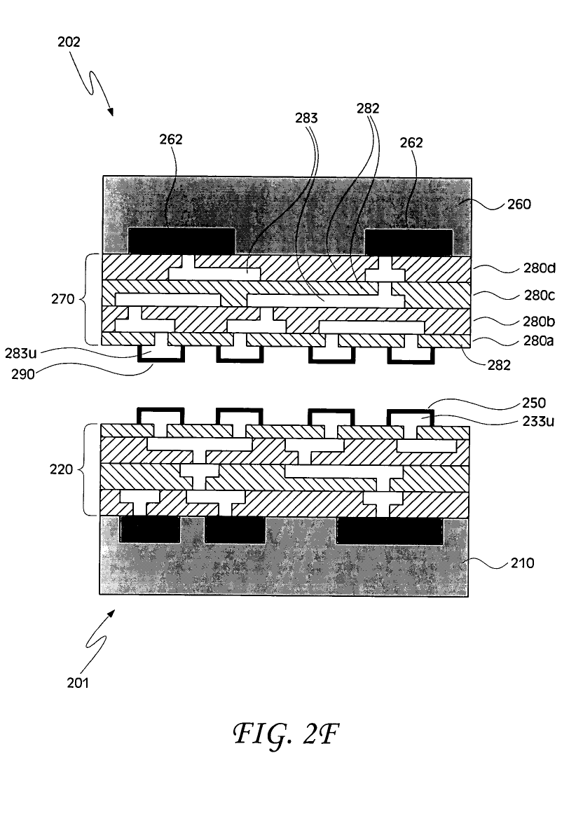

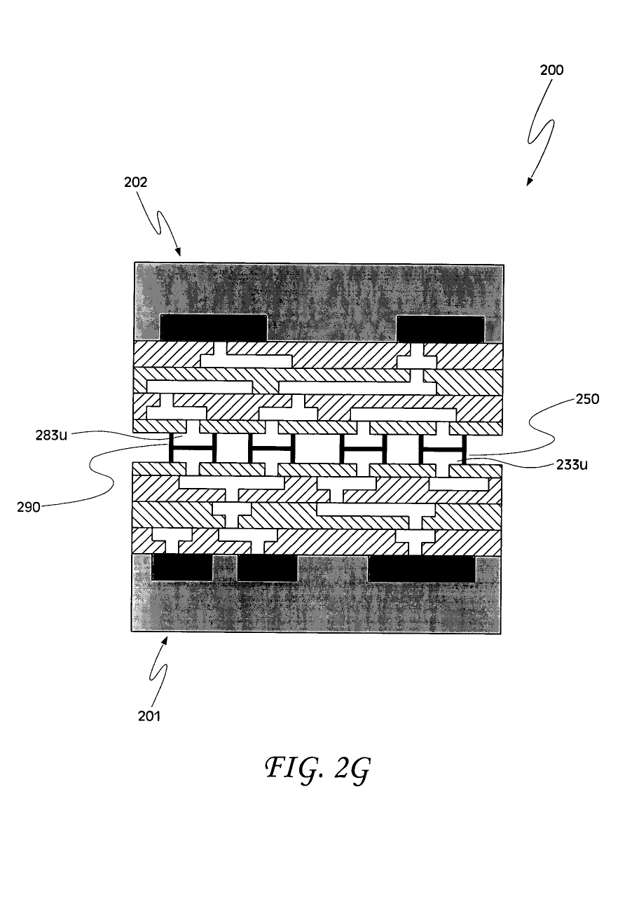

Illustrated in FIGS. 1 through 7 are embodiments of a method for bonding patterned wafers together at relatively low temperatures using a metal interlayer deposited on conductors of each wafer. One embodiment of a method 100 of bonding wafers using a metal interlayer is shown in FIG. 1. Further embodiments of the method 100 of wafer bonding with a metal interlayer are illustrated in FIGS. 2A through 7, and reference should be made to these figures along with FIG. 1, as called out in the text.

Referring first to FIGS. 2A and 2B, an embodiment of a wafer 201 is illustrated. A plan view of the wafer 201 is shown in FIG. 2A, whereas a cross-sectional elevation view of the wafer 201 is shown in FIG. 2B. Wafer 201 comprises a substrate 210 upon which integrated circuitry for a number of die 205 has been formed, each die 205 comprising one layer of a stacked die. The wafer 201 (or wafer stack, as described below) is ultimately cut into these separate devices. As shown in FIG. 2B, the integrated circuitry for each die 205 may include a number of active devices 212 (e.g., transistors, capacitors, etc.) formed on substrate 210. The wafer 201 is typically circular in shape, as shown in FIG. 2A, but may be of any suitable shape or configuration. In one embodiment, the substrate 210 comprises a Silicon substrate (e.g., a single-crystal Silicon substrate). However, it should be understood that the substrate 210 may comprise any other suitable semiconductor material, such as Gallium Arsenide (GaAs) or Germanium (Ge).

Disposed over a surface of the substrate 210 is an interconnect structure 220. Generally, the interconnect structure 220 comprises a number of levels of metalization separated by insulating layers and interconnected by vias. In one embodiment, the interconnect structure 220 includes a number of layers, including layers 230a, 230b, 230c, and 230d. Each interconnect layer 230a-d comprises a dielectric material 232 (or other insulating material) within which a number of conductors 233 (e.g., vias, traces, etc.) have been formed. The conductors 233 have feature sizes (e.g., width) on the order of 0.1 to 100 μm. The dielectric material of each layer 230a-d is commonly referred to as the “interlayer dielectric” (or “ILD”). The conductors 233u in the uppermost layer 230d will be used to electrically couple the wafer 201 with another wafer, as will be explained in greater detail below. In one embodiment, the conductors 233, 233u comprise Copper, and in a further embodiment, each layer 230a-d of the interconnect structure 220 is formed using dual damascene techniques. However, it should be understood that the conductors 233, 233u may comprise any other suitable conductive material—e.g., Aluminum (Al), Tungsten (W), Gold (Au), Silver (Ag), etc.—and that each layer 230a-d of interconnect structure 220 may be constructed using any other suitable fabrication techniques (e.g., single damascene).

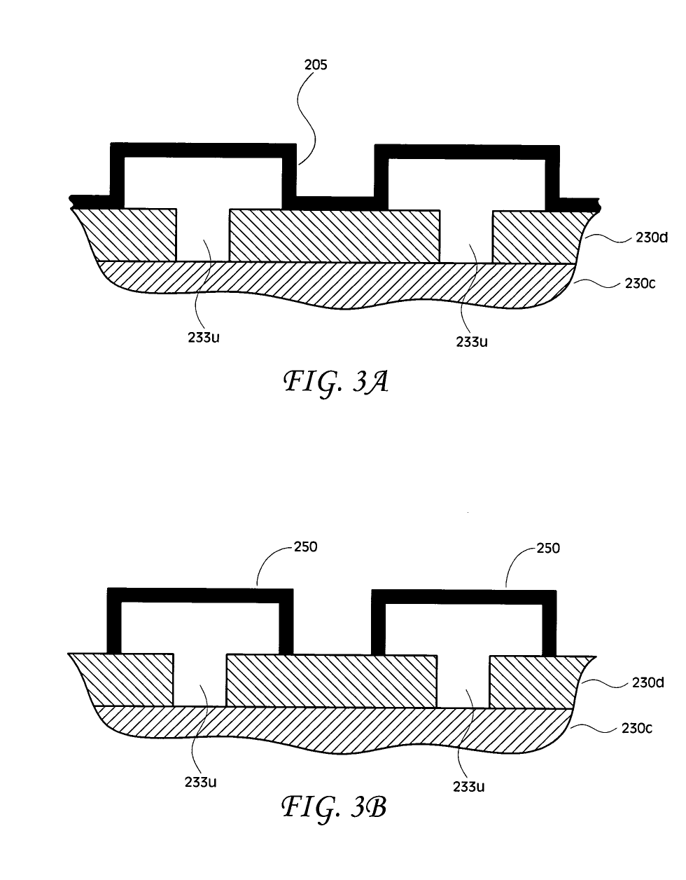

It should be noted that, in each of FIGS. 2B through 2G, only a limited number of active devices 212 and conductors 233, 233u are shown for ease of illustration and clarity. However, as will be appreciated by those of ordinary skill in the art, the integrated circuitry associated with each die 205 on wafer 201 may, in practice, include millions or even tens of millions of active devices 212 and, further, the interconnect structure 220 associated with each die 205 may include tens or hundreds of conductors 233 on each of the interconnect layers 230a-d. Thus, it should be understood that FIGS. 2A through 2G (as well as FIGS. 3A through 7) are simplified schematic representations of the wafer 201 presented merely as an aid to understanding the disclosed embodiments and, further, that no unnecessary limitations should be drawn from these schematic representations.

Turning now to the wafer bonding method shown in FIG. 1, in one embodiment, dielectric material from the uppermost interconnect layer is removed to further expose the conductors, as set forth at block 110. This is illustrated in FIG. 2C, where portions 239 of the uppermost interconnect layer 230d have been removed to expose additional surface area of the upper conductors 233u. The dielectric material may be removed using any suitable material removal process, such as a selective etching process. After removal of portions 239 of the upper interconnect layer 230d, the conductors 233u extend above the upper interconnect layer to a height of between 10 and 500 nm.

Copper, as well as other metals, readily form a native oxide in the presence of ambient air (or other oxygen containing atmosphere). This is also illustrated in FIG. 2C, which shows native oxide layer 240 formed over exposed surfaces of upper conductors 233u. This corrosion can adversely effect the performance and reliability of metal-to-metal bonds, and when such a native oxide 240 forms on conductors 233u, it may be desirable to remove the oxide. Accordingly, in one embodiment, the native oxide is removed from the exposed surfaces of the upper conductors, as set forth at block 120 in FIG. 1. This is illustrated in FIG. 2D, where the native oxide layer 240 has now been removed from the upper conductors 233u. In one embodiment, the native oxide 240 is removed by a chemical etch process using a mildly acidic or mildly basic solution. However, any other suitable material removal process may be used to remove the oxide layer 240. After removal of the native oxide, the wafer 201 may be held in a controlled environment (e.g., a processing chamber), where the formation of further oxides can be minimized.

Referring now to block 130 in FIG. 1, a layer of metal is deposited on the upper conductors. This is illustrated in FIG. 2E, where a metal layer 250 has been deposited on the exposed surfaces of the conductors 233u, this layer of metal 250 being referred to herein as a “metal interlayer.” In one embodiment, the metal interlayer 250 comprises any metal that facilitates bonding of the conductors 233u on wafer 201 to corresponding conductors of another wafer, as will be described below. In another embodiment, the metal interlayer 250 comprises any metal that facilitates bonding of the metal interlayer on each of the conductors 233u of wafer 201 to a metal interlayer on each of a number of corresponding conductors of another wafer, as will also be described below. In a further embodiment, the metal interlayer 250 comprises a metal that enables the bonding of wafer 201 with another wafer at a relatively low temperature (e.g., 300° C., or less), which can increase throughput. In yet another embodiment, the metal interlayer 250 comprises a metal that inhibits corrosion of the upper conductors 233u (e.g., the formation of native oxides, as described above), and in yet a further embodiment, the metal interlayer 250 comprises a metal that can inhibit electromigration of the conductor material (of conductors 233u) to surrounding structures. In one embodiment, the metal layer 250 comprises Silver (Ag). In another embodiment, the metal layer 250 comprises Gold (Au). However, it should be understood that any other suitable metal—e.g., noble metals such as Ruthenium (Ru), Osmium (Os), Iridium (Ir), Palladium (Pd), Rhodium (Rh), Platinum (Pt), or alloys thereof—may be used for the metal interlayer. Metal layer 250 may be deposited using any suitable technique, and various embodiments of metal interlayer formation are illustrated in FIGS. 3A through 7.

In one embodiment, the metal interlayer 250 is formed using a blanket deposition process followed by photolithography and subsequent etching. This is illustrated in FIGS. 3A and 3B. Referring first to FIG. 3A, a blanket layer 205 of the metal has been deposited over the surfaces of upper interconnect layer 230d and conductors 233u. The metal layer 205 may be deposited using any suitable deposition technique, including chemical vapor deposition (CVD), sputtering, as well as other thin film deposition techniques. Referring now to FIG. 3B, photolithography and subsequent etching are then performed to remove metal material from surfaces of the upper interconnect layer 230d, thereby leaving a layer of metal 250 over the upper conductors 233u. The thickness of the blanket layer 290 and, hence, the final metal interlayer 250, may be between 10 and 10,000 Angstroms.

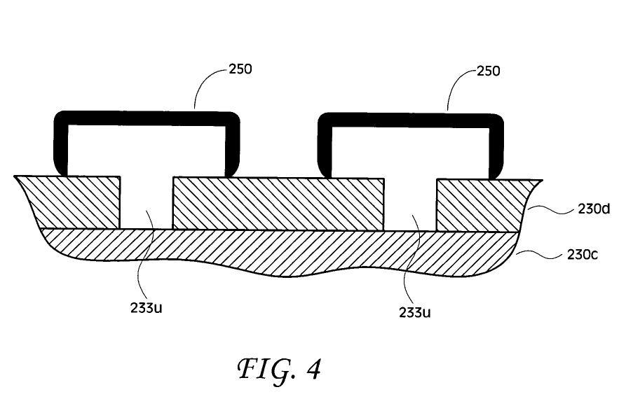

In another embodiment, as illustrated in FIG. 4, the metal interlayer 250 is formed using a selective deposition technique, wherein the metal layer 250 is selectively deposited on the upper conductors 233u. Selective deposition techniques include, by way of example only, electroplating, electroless plating, and contact displacement plating (i.e., a displacement reaction). In one embodiment, a Silver interlayer is selectively deposited on Copper conductors using a contact displacement plating process. The wafer 201 is immersed in an aqueous solution including Silver salt at a concentration of 1 to 120 grams/liter, Ammonium Sulfate at a concentration of 10 to 150 grams/liter, and Ammonium Thiosulfate at a concentration up to 150 grams/liter. In the displacement reaction, Silver ions receive electrons from Copper (i.e., Ag⁺+e⁻→Ag and Cu→Cu²⁺+2e⁻), such that Copper ions are displaced and Silver is deposited on the conductors 233u. In another embodiment, electrons are supplied by a reducing agent present in the plating solution. The plating solution may also include a complexing agent, such as glycine, citric acid, ethylene diamine tetra acetic acid (EDTA), or ethylene diamine (EDA). In a further embodiment, the plating solution includes a substance to adjust the pH of the plating solution. By way of example, the plating solution may include Ammonium Hydroxide or any other base such as TMAH (Tetramethylammonium Hydroxide) to maintain the solution's pH in a range of, for example, 8 to 13. The thickness of the selectively deposited metal interlayer 250 may be between 10 and 10,000 Angstroms.

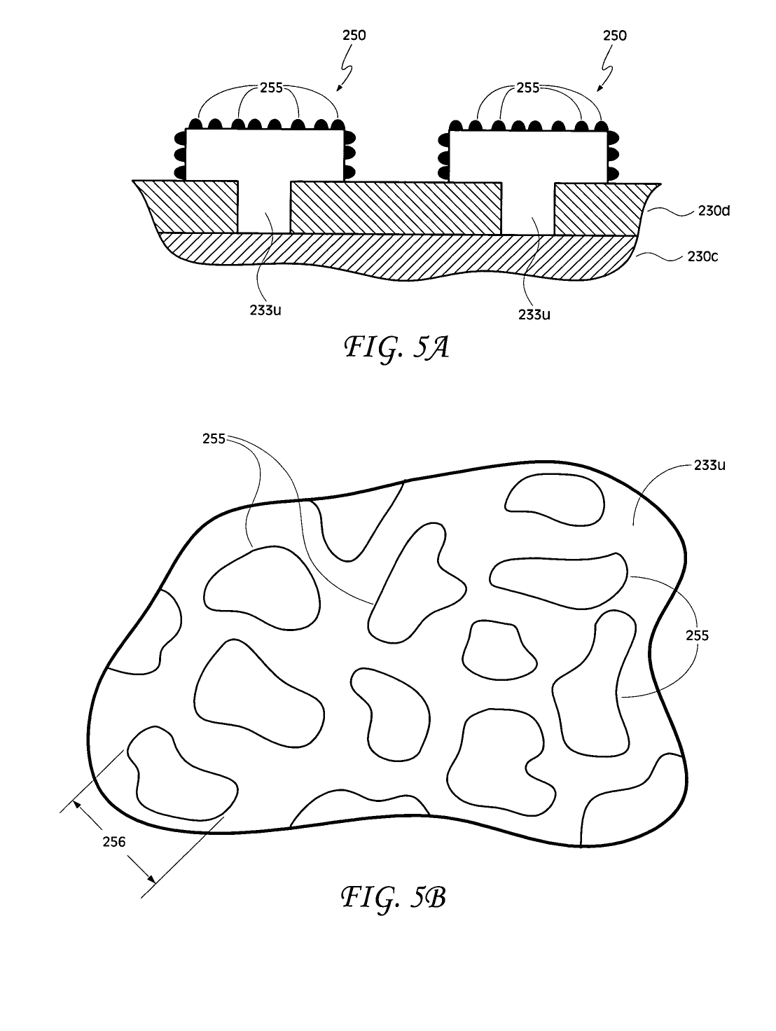

In a further embodiment, the metal interlayer 250 is deposited on the conductors as a discontinuous layer comprised of a number of islands. This is shown in FIGS. 5A and 5B, where the metal interlayer 250 on conductors 233u comprises a number of islands 255 (only a portion of a conductor 233u being shown in FIG. 5B). In the embodiment of FIGS. 5A and 5B, the metal interlayer 250 comprises any metal that, in combination with the material of conductors 233u, will form an island morphology, as will now be described in greater detail. In one embodiment, where the conductors 233ucomprise Copper, the metal interlayer 250 having an island morphology comprises Silver. However, it should be understood that other combinations of metals may provide the desired island structure (e.g., a Gold interlayer and Copper conductors).

In one embodiment, the islands 255 have an average width dimension 256 (see FIG. 5B) in a range of between 1 and 100 nm. In another embodiment, this average width is between 1 and 5 times the film thickness. The width 256 of each island 255 is small in comparison to a bulk solid and, therefore, the distance that an atom of an island 255 has to diffuse sideways to leave the center of the island is relatively small as compared to a bulk solid. Because of this property, as well as the large surface to volume ratio of the islands 255, the metal interlayer 250 will exhibit rapid diffusional creep, which is a deformation mechanism in which stress is decreased by the motion of atoms to produce deformations. As a result of this enhanced diffusional creep, the island morphology of FIGS. 5A and 5B is relatively efficient at accommodating height variations on the surfaces of the conductors 233u (and surfaces of the conductors with which conductors 233u are being bonded) that might otherwise prevent or inhibit reliable bonding.

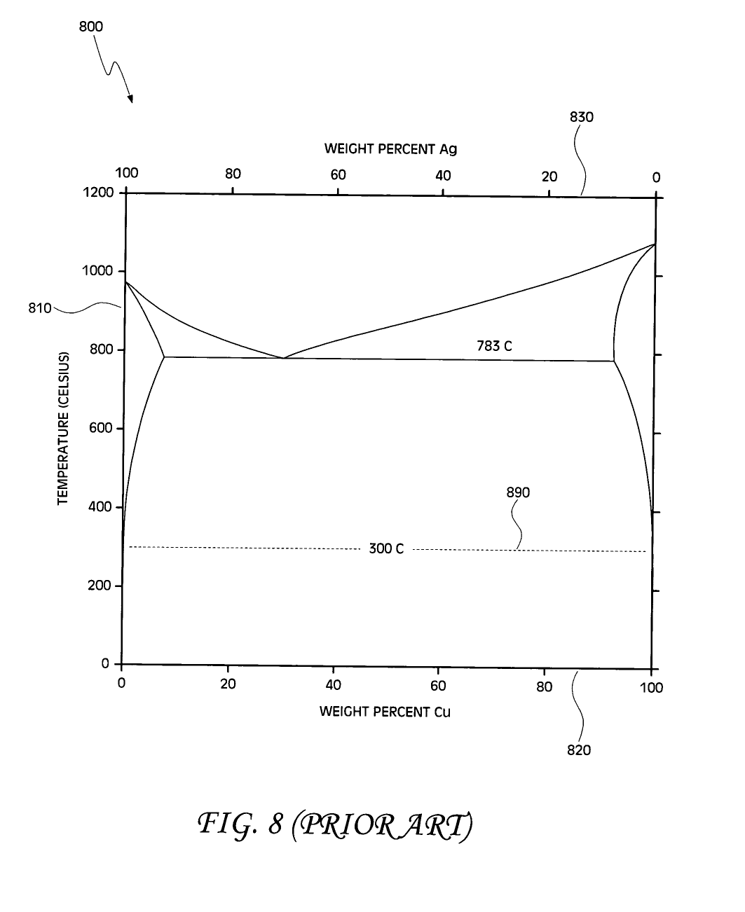

In one embodiment, which is illustrated in FIGS. 5A-5B, the islands 255 are selectively deposited on the conductors 233u using any suitable deposition method, such as contact displacement plating, electroless plating, or electroplating. The discontinuous nature of metal interlayer 250 results, at least in part, from the fact that sufficiently thin films can be unstable. In addition, to avoid interdiffusion between the metal interlayer 250 and the underlying conductors 233u, it is desirable that the metal interlayer (e.g., Silver) and the conductor metal (e.g., Copper) be insoluble. This insolubility—or, more precisely, very low solubility—is illustrated in the Cu—Ag phase diagram 800 of FIG. 8 (e.g., for a Silver interlayer and Copper conductor combination). Referring to this figure, the weight percent of Silver 820 and the weight percent of Copper 830 (on horizontal axis) are shown as a function of temperature 810 (vertical axis). At temperatures of approximately 300° C. (see curve 890) and less, there is no appreciable mixing between Copper and Silver. If the Silver does not diffuse into the Copper and the Silver interlayer is sufficiently thin (approximately 10 to 5,000 Angstroms in one embodiment), this thin Silver interlayer will agglomerate into small islands due to surface instabilities (which are influenced by factors such as grain boundaries, interface energy, and surface energy). Although the preceding discussion is presented using the example of Silver and Copper, those of ordinary skill in the art will appreciate that may other metal combinations can produce this island morphology, as noted above.

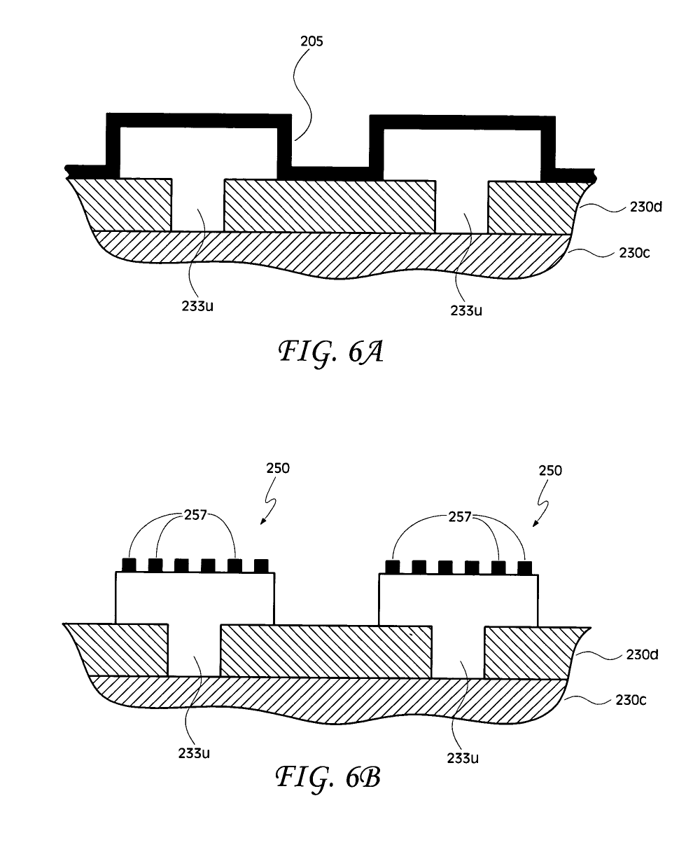

In a further embodiment, which is illustrated in FIGS. 6A and 6B, an island morphology is created using a blanket (or selective) deposition process, followed by photolithography and subsequent etching. Referring to FIG. 6A, a blanket layer 205 of metal has been deposited over the surfaces of upper interconnect layer 230d and conductors 233u. The metal layer 205 may be deposited using any suitable deposition technique, including chemical vapor deposition (CVD), sputtering, as well as other thin film deposition techniques. Photolithography and subsequent etching are then performed to remove metal material from surfaces of the upper interconnect layer 230d and portions of the upper conductors 233u. As shown in FIG. 6B, the result is a metal interlayer 250 comprising of a number of islands 257.

Returning to FIG. 1, and block 140 in particular, the wafer is aligned with another wafer for bonding. This is illustrated in FIG. 2F, where wafer 201 has been aligned with a second wafer 202. Second wafer 202 is similar to wafer 201 described above, and this wafer includes a substrate 260 upon which the integrated circuitry for each of a number of integrated circuit die has been formed, the integrated circuitry associated with each die including a number of active devices 262. In one embodiment, the substrate 260 comprises a Silicon substrate (e.g., a single-crystal Silicon substrate), but it should be understood that substrate 260 may comprise any other suitable semiconductor material (e.g., GaAs, Ge, etc.).

Disposed over a surface of the substrate is an interconnect structure 270, which structure generally comprises a number of levels of metalization separated by insulating layers and interconnected by vias. In one embodiment, interconnect structure 270 includes a number of layers, including layers 280a, 280b, 280c, and 280d. Each interconnect layer 280a-d comprises a dielectric material 282 (or other insulative material) within which a number of conductors 283 (e.g., vias, traces, etc.) have been formed. Conductors 283 have feature sizes (e.g., width) on the order of 0.1 to 100 μm. During wafer bonding, as described below, the conductors 283u in the uppermost ILD layer 230d will be electrically coupled with the upper conductors 233u of first wafer 201. In one embodiment, the conductors 283, 283u comprise Copper, and in a further embodiment, each layer 230a-d of the interconnect structure 220 is formed using dual damascene techniques. It should be understood, however, that the conductors 283, 283u may comprise any other suitable conductive material—e.g., Aluminum, Tungsten, Gold, Silver, etc.—and that each layer 230a-d of interconnect structure 220 may be constructed using any other suitable fabrication techniques (e.g., single damascene).

It should again be noted that, in each of FIGS. 2F through 2G, only a limited number of active devices 262 and conductors 283, 283u are shown on wafer 202 for ease of illustration and clarity. However, as will be appreciated by those of ordinary skill in the art, the integrated circuitry associated with each die on wafer 202 may, in practice, include millions or even tens of millions of active devices 262 and, further, the interconnect structure 270 associated with each die may include tens or hundreds of conductors 283 on each of the interconnect layers 280a-d. Thus, it should be understood that FIGS. 2F and 2G are simplified schematic representations of the wafer 202 (and wafer 201, as noted above) presented merely as an aid to understanding the disclosed embodiments and, further, that no unnecessary limitations should be drawn from these schematic representations.

In one embodiment, a metal interlayer 290 is formed on the conductors 283u of the uppermost layer 280d in a manner similar to that described above (see block 130 and accompanying text and figures). The metal interlayer 290 on conductors 283u in the uppermost interconnect layer 280d of second wafer 202 and the metal interlayer 250 on conductors 233u in the uppermost interconnect layer 230d of wafer 201 will both facilitate bonding between the conductors 233u, 283u, as described below. The metal interlayers 250, 290 may, in one embodiment, comprise the same metal (e.g., Silver), but in another embodiment, the metal interlayers 250, 290 are constructed from different metals (e.g., Silver and Gold). In yet another embodiment, irrespective of whether the metal interlayers 250, 290 comprise the same or dissimilar metals, the conductors 233u, 283u of the first and second wafers 201, 202, respectively, comprise the same material (e.g., Copper). However, in a further embodiment—again, irrespective of whether the metal interlayers 250, 290 are the same or dissimilar—the conductors 233u, 283u comprise different metals (e.g., Copper and Aluminum). In yet a further embodiment, a metal interlayer is formed on the conductors of only one of the wafers (e.g., metal interlayers 250 on wafer 201), whereas the other wafer (e.g., wafer 202) does not have a metal interlayer formed on its conductors (i.e., conductors 283u on wafer 202 do not include the metal interlayer 290).

Generally, the wafers 201, 202 will be of the same size and shape; however, it should be understood that these wafers may be of differing size and/or configuration. Also, the wafers 201, 202 may comprise the same material (e.g., Si, GaAs, Ge, etc.), or the wafers 201, 202 may comprise different materials (e.g., wafer 201 comprising Si and wafer 202 comprising GaAs). Further, although the wafers 201, 202 shown in the figures have the same general construction (e.g., a substrate having an interconnect structure formed thereon, wherein the interconnect structure comprises a number of dielectric layers having conductors), it should be understood that the wafers 201, 202 may have different architectures or be fabricated using differing construction techniques. Also, the wafers 201, 202 may be fabricated using different process flows. In one embodiment, one of the wafers (e.g., wafer 201) includes logic circuitry and the other wafer (e.g., wafer 202) includes memory circuitry. Thus, as will be appreciated by those of ordinary skill in the art, the disclosed embodiments are applicable to any type of wafer or combination of wafers—irrespective of size, shape, material, architecture, fabrication techniques, or process flow—and, as used herein, the term “wafer” should not be limited in scope to any particular type of wafer or wafer combination.

The wafers 201, 202 may be aligned and bonded using any suitable wafer bonding apparatus (not shown in figures). In one embodiment, the conductors 233u, 283u on the uppermost interconnect layers of the first and second wafers 201, 202, respectively, are similar in size (e.g., width) to conductors 233, 283 on underlying interconnect layers. In another embodiment, however, the conductors 233u, 283u are enlarged (relative to underlying conductors 233, 283) both to facilitate alignment and to make the wafer alignment process more tolerant of some misalignment.

Once the wafers 201, 202 are aligned, the wafers are bonded, as set forth at block 150. This is illustrated in FIG. 2G, which shows wafer 202 bonded to wafer 201 to form a wafer stack 200. More specifically, the conductors 233u on wafer 201 are bonded (both mechanically and electrically) to conductors 283u by the metal interlayers 250, 290. In one embodiment, the metal interlayers 250, 290 of the wafers 201, 202 bond to one another by diffusion bonding. Diffusion bonding may be facilitated by compressing the wafers 201, 202 together (e.g., at a pressure between 0.1 and 1 MPa) and/or by bonding at an elevated temperature (e.g., higher than 100° C.). It should be understood, however, that the disclosed embodiments are not limited to diffusion bonding and, further, that any suitable bonding mechanism may be employed to bond the metal interlayers (or, more generally, to bond the conductors of one wafer to those of a second wafer).

In another embodiment, as noted above, only one of the wafers 201, 202 may include metal interlayers (e.g., wafer 201 includes metal interlayers 250, whereas wafer 202 includes no metal interlayers). Bonding may again take place using any suitable bonding mechanism. For example, diffusion bonding may occur between the metal interlayer on one wafer and the conductors of the other wafer.

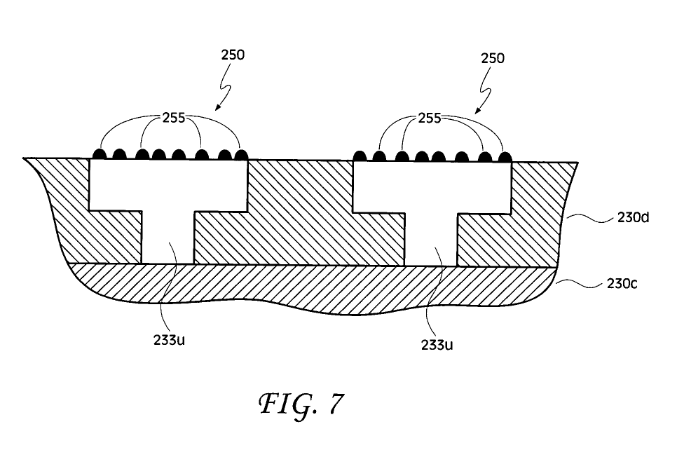

In yet a further embodiment of the method of bonding wafers using a metal interlayer, dielectric material is not removed from the upper interconnect layer 230d (or 280d)—i.e., the action recited in block 110 is not performed—thereby lowering processing time and costs. This is illustrated in FIG. 7, which shows a metal interlayer 250 comprising a number of islands 255—or other metal interlayer (e.g., see FIGS. 3A-3B, 4, and 6A-6B)—formed on conductors 233u, wherein no portions of the upper interconnect layer 230d have been removed by etching (or other material removal process).

In yet another embodiment, rather than depositing a metal interlayer on the upper conductors 233u, 283u of either one or both of the wafers 201, 202, the upper conductors are themselves comprised of a metal that is capable of bonding at a relatively low temperature (e.g., 300° C., or less). In one embodiment, the upper conductors 233u of the interconnect 220 on first wafer 201 (and/or conductors 283u of interconnect 270 on second wafer 202) comprise Silver, and in another embodiment, the upper conductors 233u of first wafer 201 (and/or conductors 283u of second wafer 202) comprise Gold. However, it should be understood that the conductors 233u (and/or conductors 283u) may comprise any other suitable metal (e.g., a noble metal such as Ruthenium, Osmium, Iridium, Palladium, Rhodium, Platinum, or an alloy thereof). Also, the upper conductors 233u, 283u of the first and second wafers 201, 202, respectively, may comprise the same metal (e.g., Silver) or, in an alternative embodiment, different metals (e.g., Silver and Gold, Silver and Copper, etc.). Any combination of metals may be selected for the conductors 233u, 283u in the uppermost ILD layers of the first and second wafer interconnects 220, 270, so long as the conductors 233u, 283u can be bonded together at a relatively low temperature.

The embodiments for wafer bonding described above may be used to form a wafer stack comprising any suitable number and type of wafers that have been bonded to one another using a metal interlayer. The use of the disclosed metal interlayer can significantly lower the bonding temperature (e.g., 300° C., or less), thereby reducing thermal cycle times and, accordingly, processing time. Thus, throughput and efficiency are increased. Also, by inhibiting corrosion and electromigration, and by minimizing thermal stresses, reliability of the wafer-to-wafer bond is improved.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. A method comprising:
depositing a layer of a metal on a number of conductors disposed on a surface of a wafer; and
bonding the conductors of the wafer to corresponding conductors on a surface of a second wafer using the metal layer.

2. The method of claim 1, further comprising, prior to depositing the metal layer on the conductors, removing dielectric material from the surface of the wafer.

3. The method of claim 1, further comprising, prior to depositing the metal layer on the conductors, removing native oxide from the conductors.

4. The method of claim 1, wherein the conductors comprise Copper.

5. The method of claim 1, wherein the metal comprises one of Silver, Gold, Ruthenium, Osmium, Iridium, Palladium, Rhodium, and Platinum.

6. The method of claim 1, wherein the bonding of the conductors of the wafer to the corresponding conductors of the second wafer is performed at a temperature between approximately 100 and 300 degrees Celsius.

7. The method of claim 1, wherein depositing the layer of metal on the conductors comprises:
forming a blanket layer of the metal over the conductors and the surface of the wafer; and removing the metal from the wafer surfaces.

8. The method of claim 1, wherein depositing the layer of metal on the conductors comprises selectively depositing the metal on the conductors.

9. The method of claim 8, wherein selectively depositing the metal on the conductors comprises one of an electroless plating process, an electroplating process, and a contact displacement plating process.

10. The method of claim 1, wherein the metal layer on each of the conductors comprises a number of islands.

11. The method of claim 10, wherein the islands are selectively deposited on the conductors.

12. The method of claim 10, wherein the islands are formed by a process comprising:
depositing a blanket layer of the metal over the conductors and the surface of the wafer; and
removing the blanket metal layer from the wafer surface and from portions of each conductor to form the number of islands on each conductor.

13. A method comprising:
depositing a layer of a first metal on a number of conductors disposed on a first wafer;
depositing a layer of a second metal on a number of conductors disposed on a second wafer;
aligning the first wafer with the second wafer; and
bonding the metal layer on the conductors of the first wafer with the metal layer on the conductors of the second wafer.

14. The method of claim 13, further comprising, prior to depositing the metal layer on the conductors of the first and second wafers, removing dielectric material from a surface of each of the first and second wafers.

15. The method of claim 13, further comprising, prior to depositing the metal layer on the conductors of the first and second wafers, removing native oxide from the conductors of each of the first and second wafers.

16. The method of claim 13, wherein the conductors of each of the first and second wafers comprise the same metal.

17. The method of claim 16, wherein the conductors of each of the first and second wafers comprise Copper.

18. The method of claim 13, wherein the first metal and the second metal are the same.

19. The method of claim 13, wherein the first metal and the second metal are different.

20. The method of claim 13, wherein each of the first and second metals comprises one of Silver, Gold, Ruthenium, Osmium, Iridium, Palladium, Rhodium, and Platinum.

21. The method of claim 13, wherein the bonding of the conductors of the first wafer to the corresponding conductors of the second wafer is performed at a temperature between approximately 100 and 300 degrees Celsius.

22. The method of claim 13, wherein depositing the metal layer on the conductors of each of the first and second wafers comprises:
forming a blanket metal layer over the conductors and a surface of the wafer; and
removing the blanket metal layer from the wafer surface.

23. The method of claim 13, wherein depositing the metal layer on the conductors of each of the first and second wafers comprises selectively depositing the metal layer on the conductors.

24. The method of claim 23, wherein selectively depositing the metal layer on the conductors comprises one of an electroless plating process, an electroplating process, and a contact displacement plating process.

25. The method of claim 13, wherein the metal layer on the conductors of at least one of the first and second wafers comprises a number of islands.

26. The method of claim 25, wherein the islands are selectively deposited on the conductors.

27. The method of claim 25, wherein the islands are formed by a process comprising:
depositing a blanket metal layer over each of the conductors and a surface of the wafer; and
removing the blanket metal layer from the wafer surface and from portions of each conductor to form the number of islands on each conductor.

28. A wafer stack comprising:
a first wafer including a number of conductors disposed on a surface of the first wafer, each of the conductors having a layer of metal formed thereon; and
a second wafer including a number of conductors disposed on a surface of the second wafer, each of the conductors having a layer of metal formed thereon;
wherein the metal layer of each conductor of the first wafer is bonded to the metal layer on a corresponding conductor of the second wafer.

29. The wafer stack of claim 28, wherein the conductors on each of the first and second wafers comprise the same metal.

30. The wafer stack of claim 29, wherein the conductors on each of the first and second wafers comprise Copper.

31. The wafer stack of claim 28, wherein the metal layer on each conductor of the first wafer and the metal layer on each conductor of the second wafer comprises the same metal.

32. The wafer stack of claim 28, wherein the metal layer on each conductor of the first wafer comprises a first metal and the metal layer on each conductor of the second wafer comprises a second, different metal.

33. The wafer stack of claim 28, wherein the metal layer on each conductor on each of the first and second wafers comprises one of Silver, Gold, Ruthenium, Osmium, Iridium, Palladium, Rhodium, and Platinum.

34. The wafer stack of claim 28, wherein the first and second wafers comprise the same material.

35. The wafer stack of claim 28, wherein the first wafer comprises one material and the second wafer comprises a different material.

36. The wafer stack of claim 28, wherein the first wafer includes logic circuitry and the second wafer includes memory circuitry.

37. A wafer stack comprising:
a first wafer, the first wafer having an interconnect including an uppermost dielectric layer and a number of lower dielectric layers, each lower dielectric layer including a number of conductors comprised of a first metal and the uppermost dielectric layer including a number of conductors comprised of a third metal; and
a second wafer, the second wafer having an interconnect including an uppermost dielectric layer and a number of lower dielectric layers, each lower dielectric layer including a number of conductors comprised of a second metal and the uppermost dielectric layer including a number of conductors comprised of a fourth metal;
wherein the conductors comprised of the third metal and the conductors comprised of the fourth metal are capable of bonding together at a temperature of approximately 300° Celsius or less; and
wherein the conductors of the uppermost dielectric layer of the first wafer are bonded to the conductors of the uppermost dielectric layer of the second wafer.

38. The wafer stack of claim 37, wherein the first and second metals comprise the same metal.

39. The wafer stack of claim 38, wherein the first and second metals comprise Copper.

40. The wafer stack of claim 37, wherein the third and fourth metals comprise the same metal.

41. The wafer stack of claim 37, wherein each of the third and fourth metals comprise one of Silver, Gold, Ruthenium, Osmium, Iridium, Palladium, Rhodium, Platinum.

42. The wafer stack of claim 37, wherein the third metal comprises one of Silver, Gold, Ruthenium, Osmium, Iridium, Palladium, Rhodium, Platinum and the fourth metal comprises Copper.
